(19) United States
(12) Patent Application Publication
(10) Pub. No.: US 2024/0069435 A1
(43) Pub. Date: Feb. 29, 2024

(54) FILM FORMING APPARATUS, FILM FORMING METHOD, MANUFACTURING METHOD OF ARTICLE, AND STORAGE MEDIUM

(71) Applicant: CANON KABUSHIKI KAISHA, Tokyo (JP)

(72) Inventor: SHINTARO NARIOKA, Tochigi (JP)

(21) Appl. No.: 18/363,957

(22) Filed: Aug. 2, 2023

(30) Foreign Application Priority Data
Aug. 23, 2022 (JP) 2022-132227

(51) Int. Cl. G03F 7/00; B29C 59/00; B29C 59/02

(52) U.S. Cl. CPC G03F 7/0002; B29C 59/002; B29C 59/022; B29C 59/026

(57) ABSTRACT

To suitably inhibit the curing of the protruding curable composition without impairing the fillability, a film forming apparatus comprises: a film forming operation unit configured to bring a mold into contact with a curable composition supplied to a substrate; an exposure unit configured to expose the curable composition; a moving unit configured to move the substrate from the film forming operation unit to the exposure unit; and a control unit configured to perform control such that a concentration of a first gas that inhibits curing of the curable composition becomes higher in a state in which the curable composition is exposed by the exposure unit after the substrate is moved by the moving unit than in a state in which the mold is brought into contact with the curable composition by the film forming operation unit.

### BACKGROUND OF THE INVENTION

### Field of the Invention

The present invention relates to a film forming apparatus using a curable composition, a film forming method, a manufacturing method of an article, and a storage medium.

### Description of the Related Art

The imprint technology is a technology that enables transfer of a nanoscale fine pattern and is being put into practical use as one of nanolithography technologies for mass production of magnetic storage media and semiconductor devices. In the imprint technology, a fine pattern is formed on a wafer, for example, a silicon wafer and a glass plate using a mask on which a fine pattern has been formed as an original.

This fine pattern is formed by applying a curable composition onto the wafer and photocuring the curable composition while the mask pattern is pressed against the wafer through this curable composition. Additionally, various film forming technologies applying this are also being put into practical use.

After the mask is pressed against the curable composition, the curable composition flows into the recess portion of the mask pattern due to surface tension. Additionally, if the pattern formed in the previous step remains on the wafer side, the curable composition may also flow into the recess portion of the wafer. Furthermore, a resin may also flow to the edge portions of the mask and the wafer, and the excess curable composition can protrude outside the mask edge and the effective region of the wafer.

After the curable composition is filled in the gap between the mask and the wafer, the curable composition is cured. Through this curing processing, the curable composition that protrudes can also be cured. There is a concern that, during release from the mold, the cured and protruding curable composition adheres to the mask, and a part of the curable composition may fall, causing defects in the subsequent steps. Accordingly, a method for preventing the curable composition that protrudes from being cured or preventing all protrusions is needed.

During the curing of a curable composition, radicals generated by the irradiation of exposure light cause the curable composition to photo-polymerize, leading to curing. However, since the generated radicals are trapped by oxygen, the photopolymerization reaction is hindered in the oxygen atmosphere.

This phenomenon is known as oxygen inhibition. Japanese Patent No. 6,761,329 discloses a method for inhibiting the curing of a curable composition that protrudes by supplying a gas that inhibits the curing of the curable composition to an area around the pattern region by utilizing this phenomenon.

To take measures against bubble defects, in a conventional film forming apparatus, it is typical to saturate the gap between the mask and the wafer with a gas, such as helium, that promote the fillability of a curable composition, which is highly soluble, highly diffusible, or both, to the curable composition. Since these gases normally do not contain oxygen, there has been a concern that the curable composition that protrudes is more easily cured under the environment of these gases.

In contrast, a gas that inhibits the curing of a curable composition does not necessarily promote the fillability. Therefore, there has been a concern that the filling property may be impaired depending on the timing of performing the replacement with the gas that inhibits the curing of the curable composition in the protruding portion. Note that the drawbacks as described above also occur in a film forming apparatus, for example, a planarization apparatus that planarizes the curable composition on a substrate by using a mask having a flat surface.

Accordingly, one of the objects of the present invention is providing a film forming apparatus that suitably inhibits the curing of a curable composition that protrudes, without impairing the fillability.

### SUMMARY OF THE INVENTION

In order to achieve the object, a film forming apparatus as one aspect of the present invention comprising:
a film forming operation unit configured to bring a mold into contact with a curable composition supplied to a substrate; an exposure unit configured to expose the curable composition; a moving unit configured to move the substrate from the film forming operation unit to the exposure unit; and a control unit, including at least one processor or circuit, configured to perform control such that a concentration of a first gas that inhibits curing of the curable composition becomes higher in a state in which the curable composition is exposed by the exposure unit after the substrate is moved by the moving unit than in a state in which the mold is brought into contact with the curable composition by the film forming operation unit.

Further features of the present invention will become apparent from the following description of embodiments with reference to the attached drawings.

### BRIEF DESCRIPTION OF THE DRAWINGS

FIG. 1 is a diagram showing a configuration example of a film forming apparatus IMP before a film forming operation in the first embodiment.

FIG. 2 is a diagram showing a configuration example of a gas supply unit in the first embodiment.

FIG. 3 is a flow chart showing an example of a processing procedure of a film forming apparatus in the first embodiment.

FIG. 4 is a diagram showing a state of the film forming apparatus during exposure in the first embodiment.

FIG. 5 is a diagram showing a configuration example of a gas supply unit in the second embodiment.

FIG. 6 is a flowchart showing an example of a processing procedure of a film forming apparatus in the second embodiment.

FIG. 7 is a diagram showing a state of the film forming apparatus during exposure in the second embodiment.

FIG. 8 is a diagram showing a modification of the gas supply unit in the second embodiment.

FIG. 9 is a diagram showing a configuration example of the gas supply unit in the third embodiment.

FIG. 10 is a flowchart showing an example of a processing procedure of a film forming apparatus in the third embodiment.

FIG. 11 is a flowchart showing a processing procedure of a modification of the film forming apparatus in the third embodiment.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate description will be omitted or simplified.

### First Embodiment

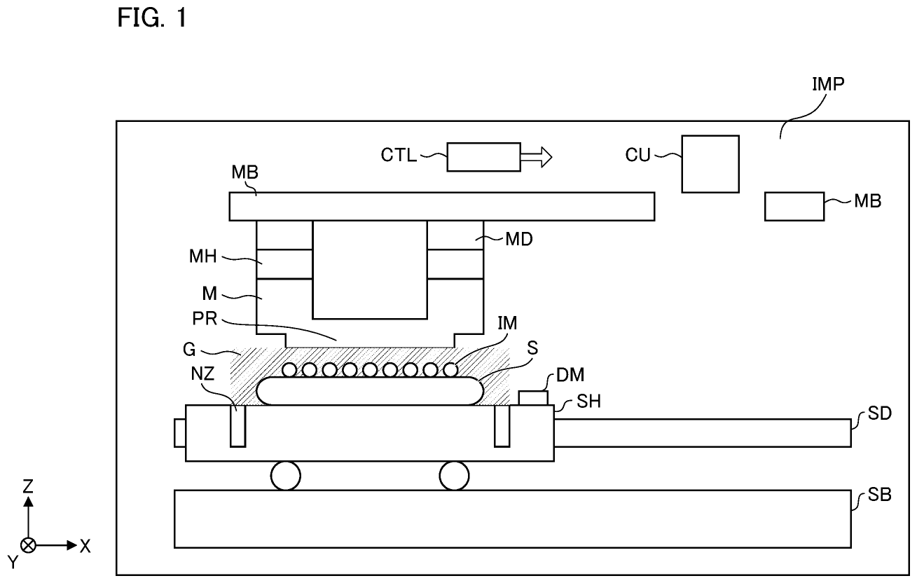

FIG. 1 is a diagram showing a configuration example of a film forming apparatus IMP before a film forming operation in the first embodiment. The film forming apparatus IMP executes the processing of bringing a plurality of droplets of the curable composition IM placed on the substrate S into contact with the mold M, and forming a film of the curable composition IM in a space between the substrate S and the mold M.

Here, the substrate S and the mold M may be disposed in reverse. Then, a plurality of droplets of the curable composition IM placed on the mold M may be brought into contact with the substrate S on the upper side to form a film of the curable composition IM in the space between the mold M and the substrate S.

That is, when generalized, the film forming apparatus IMP is an apparatus that executes the processing of bringing a plurality of droplets of the curable composition IM placed on a first member into contact with a second member, and forming a film of the curable composition IM in a space between the first member and the second member. In the following description, an example in which the first member is the substrate S and the second member is the mold M will be explained. However, the first member may be the mold M and the second member may be the substrate S, and in this case, the substrate S and the mold M are exchanged in the following explanation.

In the film forming apparatus, by using the mold M having a pattern, the pattern of the mold M is transferred onto the curable composition IM on the substrate S. In this case, in the film forming apparatus, the mold M having a pattern region PR in which the pattern is provided is used. In the film forming apparatus, the curable composition IM on the substrate S and the pattern region PR of the mold M are brought into contact with each other to fill the space between the region of the substrate S where the pattern is to be formed and the mold M with the curable composition, and then the curable composition IM is exposed and cured.

Thereby, the pattern of the pattern region PR of the mold M is transferred onto the curable composition IM on the substrate S. Note that the mold M does not necessarily have a pattern, and may be flat. Additionally, the cured product of the curable composition IM that is formed may also be flat. That is, the film forming apparatus includes a planarization apparatus.

As a curable composition, a material that cures by applying curing energy is used. Electromagnetic waves, heat, and the like are used as curing energy. The electromagnetic waves are light whose wavelength is selected from the range of 10 nm or more and 1 mm or less, such as infrared rays, visible rays, and ultraviolet rays. The curable composition is a composition that is cured by light irradiation or heating.

Among these, the photocurable composition that is cured by light irradiation contains at least a polymerizable compound and a photopolymerization initiator, and may further contain a non-polymerizable compound or a solvent according to necessity. The non-polymerizable compound is at least one selected from the group including sensitizers, hydrogen donors, internal release agents, surfactants, antioxidants, polymer components, and the like.

The viscosity (viscosity at 25° C.) of the curable composition is, for example, 1 mPa·s or more and 1,000 mPa·s or less. Materials for the substrate include, for example, glass, ceramics, metals, semiconductors, and resins. A member made of a material that is different from the material of the substrate may be provided on the surface of the substrate, according to necessity. The substrate is, for example, a silicon wafer, a compound semiconductor wafer, and quartz glass.

In this specification and the accompanying drawings, directions are explained using an XYZ coordinate system in which a direction parallel to the surface of the substrate S is the XY plane. The directions that are respectively parallel to the X axis, the Y axis, and the Z axis in the XYZ coordinate system are set to the X direction, the Y direction, and the Z direction, and rotations about the X axis, the Y axis, and the Z axis are respectively set to θX, θY, and θZ.

Control or drive with respect to the X-axis means control or drive with respect to the direction parallel to the X-axis, control or drive with respect to Y-axis means control or drive with respect to the direction parallel to the Y-axis, and control or drive with respect to Z-axis means control or drive with respect to with respect to the direction parallel to the Z-axis. Additionally, control or driving with respect to the θX-axis means control or driving with respect to the rotation around the axis parallel to the X-axis, control or driving with respect to the θY-axis means control or driving with respect to the rotation around the axis parallel to the Y-axis, and control or driving with respect to the θZ-axis means control or driving with respect to the rotation around the axis parallel to the Z-axis. Additionally, the position is information that can be specified based on the coordinates of the X-axis, the Y-axis, and the Z-axis, and the orientation is information that can be specified by the values of the θX-axis, the θY-axis, and the θZ-axis. Positioning means controlling position and/or orientation.

The film forming apparatus IMP includes a substrate holding unit SH that holds the substrate S, a substrate driving unit SD that drives the substrate S by driving the substrate holder SH, and a support base SB that supports the substrate driver SD. A part of the substrate holding unit SH is provided with an illuminance measuring unit DM that measures illuminance. Additionally, the film forming apparatus IMP includes a mold holding unit MH that holds the mold M, a mold driving unit MD that drives the mold M by driving the mold holder MH, and a mold base MB that holds the mold driving unit MD.

The substrate driving unit SD and the mold driving unit MD configure a relative driving mechanism that drives at least one of the substrate S and the mold M so that the relative position between the substrate S and the mold M is adjusted. Here, the mold holding unit MH and the mold driving unit MD that drives the mold M by driving the mold holding unit MH function as a film forming operation unit.

The film forming operation unit brings the mold M into contact with the curable composition IM supplied onto the substrate S, and then performs driving for separating the mold M from the cured curable composition IM. Additionally, the adjustment of the relative position by the relative driving mechanism may include positioning between the substrate S and the mold M.

The substrate driving unit SD is configured to drive the substrate S with respect to a plurality of axes (for example, three axes of the X-axis, the Y-axis, and the θZ-axis, and preferably six axes of the X-axis, the Y-axis, the Z-axis, the θX-axis, the θY-axis, and the θZ-axis). The mold driving unit MD is configured to drive the mold M with respect to a plurality of axes (for example, three axes of the Z axis, the θX axis, and the θY axis, and preferably six axes of the X axis, the Y axis, the Z axis, the θX axis, the θY axis, and the θZ axis).

The film forming apparatus IMP is provided with an exposure unit CU for curing the curable composition IM that is filled in the space between the substrate S and the mold M. In the first embodiment, the exposure unit CU is disposed at a different exposure position on the XY plane from the mold driving unit MD. The exposure unit CU performs exposure by irradiating the curable composition IM with curing energy via, for example, the transparent mold M at the above-described exposure position, thereby curing the curable composition IM.

The film forming apparatus IMP includes a dispenser DSP (not illustrated) for placing, supplying, or distributing the curable composition IM on the substrate S. Note that the substrate S on which the curable composition IM has been placed by another apparatus may be carried into the film forming apparatus IMP, and in this case, the dispenser DSP does not need to be provided in the film forming apparatus IMP.

The substrate holding unit SH is provided with a gas nozzle NZ so as to surround the substrate S. The gas nozzle NZ may be in the form of one continuous groove or may be divided into a plurality of parts. In FIG. 1, nozzle cross section of the gas nozzle NZ is shown.

The gas nozzle NZ can supply gas G to fill the gap between the mold M and the substrate S and the area around the substrate S with desired gas G. In FIG. 1, the distribution of the gas G when the gas G is supplied from the gas nozzle NZ is schematically shown by hatching with oblique lines. The unhatched portion indicates being filled with air.

CTL is a control unit, and has a CPU serving as a computer and a memory that stores a computer program executed by the CPU. The CPU controls each unit of the entire film forming apparatus IMP by executing a computer program that is stored in the memory.

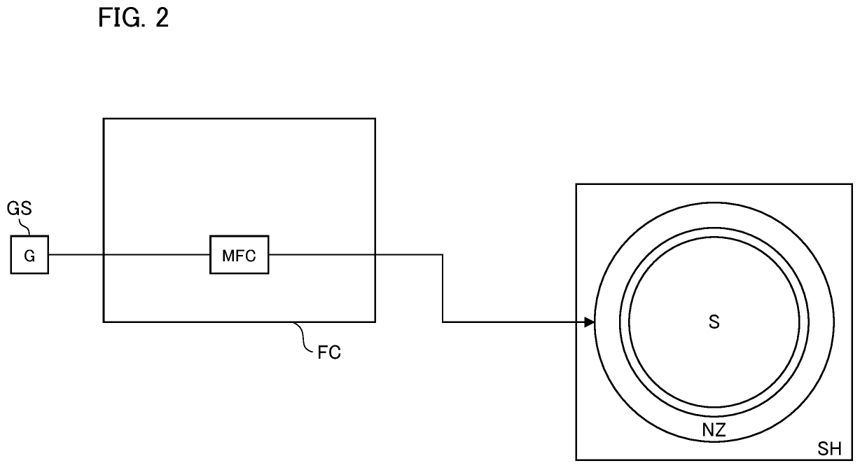

FIG. 2 is a diagram showing a configuration example of a gas supply unit of the first embodiment, and a configuration of the gas nozzle NZ of the present embodiment and a pipe leading to the gas nozzle NZ will be described with reference to FIG. 2. The gas nozzle NZ is configured in the shape of one continuous ring groove so as to surround the outer periphery of the substrate S having a substantially circular shape. The gas nozzle NZ is connected to a flow rate adjusting unit FC, and the flow rate of the gas G (second gas) supplied from the gas nozzle NZ is adjusted by the flow rate adjusting unit FC.

The flow rate adjusting unit FC may be a flow rate adjusting device such as a mass flow controller (MFC) or a combination of a flow rate adjustment valve and a mass flow meter. In FIG. 2, the gas nozzle NZ is connected to the flow rate adjusting unit FC, and the flow rate adjusting unit FC is connected to the supply source GS of the gas G (second gas). Here, a second gas supply unit is configured by the gas nozzle NZ, the flow rate adjusting unit FC, the supply source GS, and a piping connecting them, and the like.

Note that it is sufficient that the gas G (second gas) is any gas that does not inhibit the curing of the curable composition and is any gas that has high diffusivity or high solubility in the curable composition IM, such as helium and carbon dioxide.

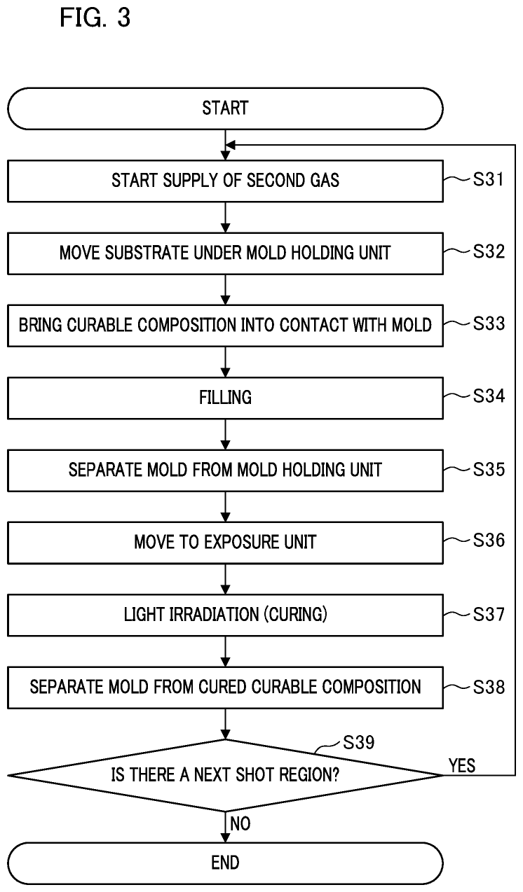

FIG. 3 is a flowchart showing an example of a processing procedure of the film forming apparatus in the first embodiment, and a method for suitably carrying out the present embodiment will be described with reference to the flowchart of FIG. 3. Note that the operation of each step in the flowchart of FIG. 3 is performed by the CPU, which serves as a computer in the control unit CTL, executing a computer program that is stored in the memory.

First, in step S31, the supply of the gas G (second gas) starts from the gas nozzle NZ that is provided in the substrate holding unit SH. Subsequently, in step S32, the substrate S to which the curable composition IM has been supplied moves to the position under the mold holding unit MH. Further, in step S33 (film forming operation step), the mold M starts to descend, and the mold M is brought into contact with the curable composition IM that has been supplied to the substrate.

After the contact, in step S34, the filling of the pattern region PR of the mold M with the curable composition IM starts, and the curable composition IM wets and spreads over the entire surface of the pattern region PR of the mold M. In this manner, in step S31, the second gas that does not inhibit the curing of the curable composition is supplied to the curable composition before the mold is brought into contact with the curable composition by the film forming operation unit in step S33.

Note that, in step S33, the supply of the gas G (second gas) is stopped at the timing when the mold M starts to descend toward the substrate S. This is because, after the mold M starts to descend toward the substrate S, the gap between the mold M and the substrate S is becoming smaller, and even if the second gas is supplied from the area around the substrate S, it is difficult for the second gas to enter the gap between the mold M and the substrate S, and therefore, even if the supply of the second gas is stopped, there are few defects.

In the first embodiment, after filling is completed in step S34, exposure is not executed there. This is because, if exposure is performed while the transparent mold M is being held by the mold holding unit MH in the case in which the pattern region PR of the mold M is larger than the mold holding unit MH as in the configuration of FIG. 1, part of exposure light is blocked by the mold holding unit MH. Additionally, a failure in which the curable composition IM is not partially cured may occur due to the blocking.

Accordingly, in the first embodiment, after the filling is completed in step S34, the mold M is separated from the mold holding unit MH in step S35. The mold M that has been separated from the mold holding unit MH is in a state in which it is placed on the substrate S via the curable composition IM.

Next, in step S36 (moving step), the substrate S on which the mold M is placed is moved to a position directly under the exposure unit CU by the substrate driving unit SD while being held by the substrate holding unit SH. That is, after the film forming operation step, the substrate is moved for the exposure step. Here, the substrate driving unit SD functions as moving unit that moves the substrate from the film forming operation unit to the exposure unit.

Note that the exposure unit CU is disposed at a position away from the mold holding unit MH to such an extent that the exposure light is not blocked by the mold holding unit MH for holding the mold. More specifically, it is desirable that a distance between the central axes of the mold holding unit MH and the exposure unit CU is larger than the outer size of the mold holding unit MH.

It is desirable that the timing at which the substrate S starts to move toward the exposure unit CU in step S36 is after the curable composition IM and the mold M start to come into contact with each other and the filling of the curable composition IM into the mold M is completed.

Here, the determination of the completion of filling may be determined as the completion of filling after a predetermined elapsed time from the start of contact between the curable composition IM and the mold M. Alternatively, the behavior of filling may be captured by a camera (not illustrated), and the determination may be made based on the image. The timing of completion of filling may be before or after the mold M is separated from the mold holding unit MH.

After the substrate S on which the mold M is placed via the curable composition IM is moved to a position directly under the exposure unit CU in step S36, the curable composition IM is exposed by irradiation with light in step S37 (exposure step), and the curable composition IM is cured by exposure light. After the curable composition IM is cured, the substrate holding unit SH on which the substrate S was placed in step S38 is moved again to a position directly under the mold holding unit MH by the substrate driving unit SD.

Then, the mold holding unit MH holds the mold M again and separates the mold M from the curable composition IM, that is, releases the mold M. Subsequently, in step S39, it is determined whether or not there is a next shot region, and when the determination is YES, the process returns to step S31, and when the determination is NO, the flow of FIG. 3 ends.

When the curable composition IM wets, spreads, and fills the entire surface of the pattern region PR of the mold M in step S34, the excess curable composition IM may protrude to the outside of the pattern region PR of the mold M. Alternatively, even at the stage in which the curable composition and the mold are brought into contact with each other in step S33, the curable composition can protrude to the substrate side along a pattern that may exist on the substrate S. Protrusion may also occur in step S36.

Then, the curable composition IM in these protruding portions can also be cured by irradiation with the exposure light in step S37. There is a concern that, during the release from the mold in step S38, the cured curable composition IM in the protruding portion adheres to the mold M, and a part of the curable composition IM falls, causing defects in the subsequent steps.

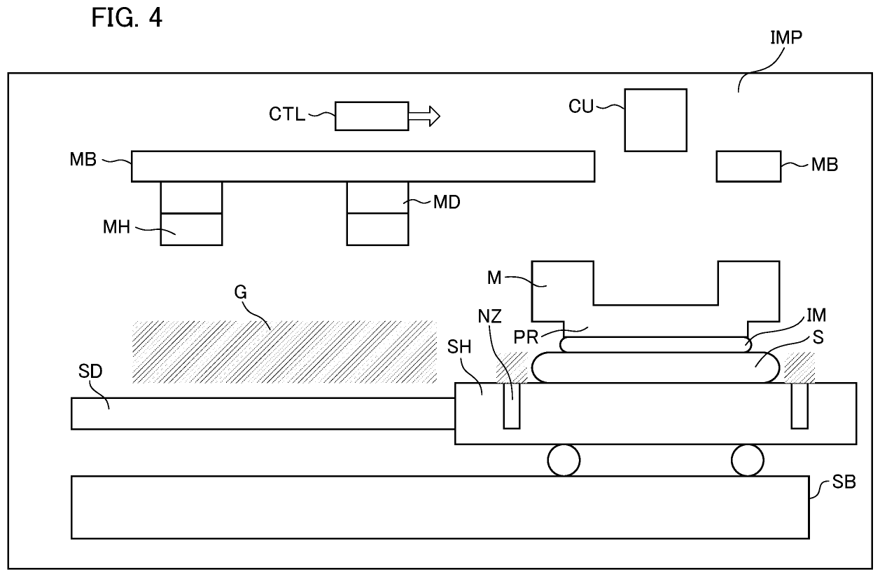

FIG. 4 is a view showing the state of the film forming apparatus during exposure according to the first embodiment, and schematically shows the distribution of the gas G immediately after the substrate S on which the mold M is placed via the curable composition IM is moved to a position directly under the exposure unit CU in step S36, by hatching with oblique lines. The unhatched portion indicates that it is filled with air.

Before the substrate S moves toward the exposure unit CU, the area around the substrate S is filled with the gas G (second gas) that has been supplied from the gas nozzle NZ, and, in this state, there is almost no air around the substrate S. That is, in the state in which the mold is brought into contact with the curable composition by the film forming operation unit, the area around the curable composition is filled with the gas G (second gas), and control is performed such that the concentration of oxygen (first gas) becomes lower than a predetermined value.

However, as the substrate S moves directly under the exposure unit CU, the gas G that has been supplied to the area around the substrate S remains in the vicinity of the mold holding unit MH. Accordingly, after the substrate S is moved to the exposure unit, the area around the substrate S is substantially filled with air. That is, in the exposure step of exposing the curable composition by the exposure unit after the substrate is moved in the moving step, a concentration of the first gas (oxygen) that inhibits the curing of the curable composition becomes equal to or higher than a predetermined value.

During the move of the substrate S, even if the gas G continues to be supplied from the gas nozzle NZ, the gas G (second gas) is mixed with air because the area around the exposure unit CU is originally filled with the air. Consequently, in the surrounding area of the substrate S, the concentration of the gas G decreases compared to when the area is filled with the gas G before the substrate S starts to move toward the exposure unit CU, resulting in an environment closer to air with a high oxygen concentration.

That is, although, in the first embodiment, the second gas is supplied to the curable composition before the mold is brought into contact with the curable composition, the amount of the second gas supplied to the curable composition in the case in which the curable composition is exposed is reduced compared to the amount of the second gas supplied at that time. Alternatively, the amount of supply of the second gas is stopped.

Accordingly, control is performed such that, in the exposure step, the concentration of the first gas that inhibits the curing of the curable composition becomes higher, as compared to the film forming operation step. Additionally, steps S31 to S39 function as control steps for performing the control as described above.

Since air contains oxygen (first gas), which is a gas that inhibits the curing of the curable composition IM, the curable composition that protrudes, as described above, is not cured by exposure, in the environment filled with air or a gas close to air. Therefore, when the substrate S is moved directly under the exposure unit CU whose surroundings are filled with air and then the exposure to the curable composition IM is performed, the curing of the curable composition in the protruding portion can be suppressed.

In this regard, the part of the curable composition IM that does not protrude is interposed between the mold M and the substrate S, and is not exposed to the air even after the substrate S moves directly under the exposure unit CU. Therefore, it is less likely to be affected by oxygen and can be sufficiently cured by exposure light. Hence, there is little concern that the curable composition IM that does not protrude is not cured.

Note that, in FIG. 1 and FIG. 4, it is assumed that the mold driving unit MD and the exposure unit CU are located in the same space having no partition. However, a partition may be provided between the mold driving unit MD and the exposure unit CU. Alternatively, the mold driving unit MD and the exposure unit CU may be configured in different chambers. By ventilating the inside of the partition when viewed from the exposure unit CU side or the inside of the chamber on the exposure unit CU side, the concentration of the gas G in these spaces can further be reduced.

As described above, in the first embodiment, control is performed such that the oxygen concentration in the space around the exposure unit CU is relatively higher than that of the oxygen concentration directly under the mold driving unit MD. That is, control is performed such that the concentration of the first gas (oxygen) is higher by performing a setting in which the concentration of the second gas becomes lower in the state in which the curable composition is exposed by the exposure unit than the state in which the mold is brought into contact with the curable composition by the film formation operating unit. Therefore, it is possible to obtain the effect of suppressing the curing of the curable composition of the protruding portion.

### Second Embodiment

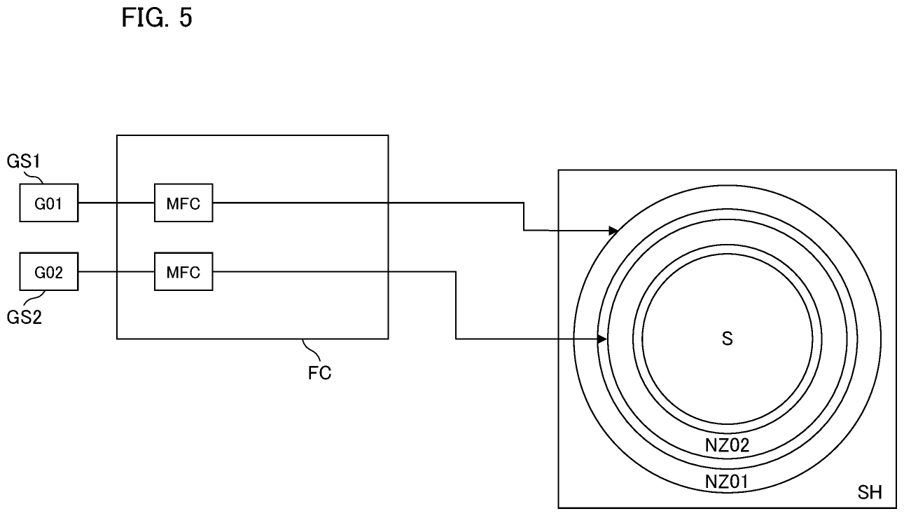

FIG. 5 is a diagram illustrating a configuration example of a gas supply unit in the second embodiment. As shown in FIG. 5, the second embodiment differs from the first embodiment in that a ring-groove-shaped gas nozzle NZ01 for the first gas G01 is further provided, in addition to a ring-groove-shaped gas nozzle NZ02 for the second gas G02 that is provided in the area around the substrate S.

That is, a first gas supply unit (gas nozzle NZ01) and a second gas supply unit (gas nozzle NZ02) are provided in the substrate holding unit. Similarly to the second gas G02, the first gas G01 is connected to the flow rate adjusting unit FC capable of adjusting the flow rate, and the flow rates are individually adjusted.

The flow rate adjusting unit FC may be a mass flow controller (MFC) or a combination of a flow rate regulating valve and a mass flow meter. In FIG. 5, the gas nozzle NZ01 is connected to the supply source GS1 of the first gas G01 via an MFC, and the gas nozzle NZ02 is connected to the supply source GS2 of the second gas G02 via another MFC.

Here, a first gas supply unit is configured by the gas nozzle NZ01, the flow rate adjusting unit FC, the supply source GS1 of the first gas G01, the piping connecting them, and the like. Additionally, a second gas supply unit is configured by the gas nozzle NZ02, the flow rate adjusting unit FC, the supply source GS2 of the second gas G02, the piping connecting them, and the like.

Note that it is sufficient that the first gas G01 is any gas that contains a predetermined concentration or more of oxygen, which is a gas that inhibits the curing of the curable composition IM. Additionally, it is sufficient that the second gas G02 is any gas that has high diffusivity or high solubility in the curable composition IM, such as helium and carbon dioxide. The second gas G02 in the second embodiment corresponds to the gas G in the first embodiment.

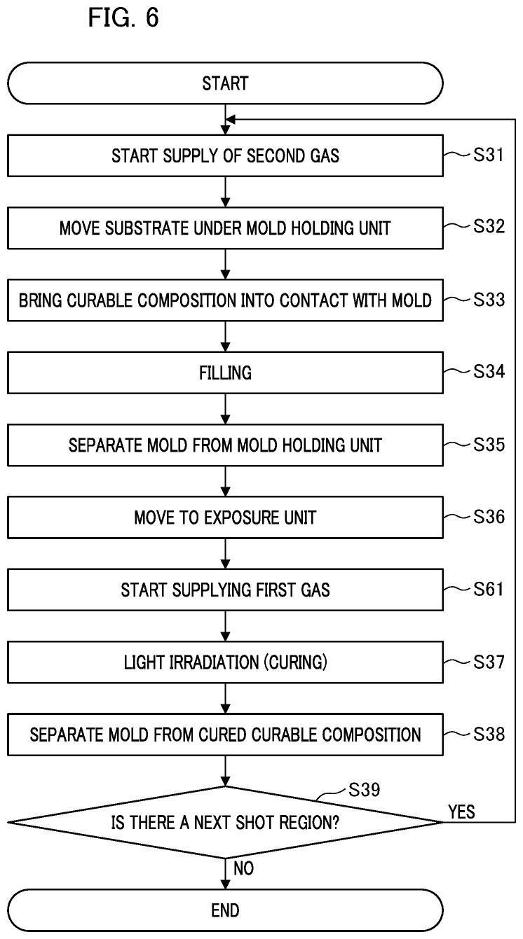

FIG. 6 is a flow chart showing an example of the processing procedure of the film forming apparatus in the second embodiment, and a preferred method of carrying out the present embodiment will be described with reference to the flow chart in FIG. 6.

Note that the operation of each step of the flowchart in FIG. 6 is performed by the CPU, which serves as a computer in the control CTL, executing a computer program that is stored in the memory. Note that steps S31 to S39 in FIG. 6 are the same processes as the steps with the same reference numerals in FIG. 3, and description thereof will be omitted.

The second embodiment is different from the first embodiment on the point that, the mold M is separated from the mold holding unit MH in step S35, and the substrate S starts moving to the exposure unit CU in step S36, and then the supply of the first gas G01 starts in step S61.

Note that the timing at which the supply of the first gas G01 starts may be after the contact between the curable composition IM and the mold M starts and the filling of the mold M with the curable composition IM is substantially completed in step S34. That is, the first gas supply unit may start supplying the first gas to the curable composition after the operation of bringing the mold into contact with the curable composition by the film forming operation unit has completed.

That is, the supply of the first gas G01 may be started in parallel to step S35 and step S36. However, it is desirable that the timing of starting the supply of the first gas G01 is before the exposure.

Thus, in the second embodiment, the first gas is supplied to the curable composition by the first gas supplying unit before the curable composition is exposed by the exposing unit after the completion of filling. Accordingly, the filling is not inhibited due to the first gas, and the curable composition that protrudes around area of the mold can be prevented from being cured due to exposure.

Note that, although the separation of the mold M from the mold holding unit MH starts in step S35 after the completion of filling in step S34, the timing of starting the separation of the mold M from the mold holding unit MH may be during the filling in step S34. Alternatively, the move of the substrate S to the exposure unit CU may be started in step S36 without waiting for the completion of filling. Determination of the completion of filling may be performed as in the first embodiment.

Additionally, it is desirable that the supply of the second gas G02 is stopped along with the start of the supply of the first gas G01. Alternatively, the supply of the second gas G02 may be stopped before the supply of the first gas G01 is started. For example, the supply of the second gas may be stopped at the timing when the mold M starts to descend toward the substrate S, as in the first embodiment.

This is because, after the mold M starts to descend toward the substrate S, the gap between the mold M and the substrate S is becoming smaller, and even if the second gas is supplied from the area around the substrate S, it is difficult for the second gas to enter the gap between the mold M and the substrate S, and therefore, even if the supply of the second gas is stopped, there are few defects.

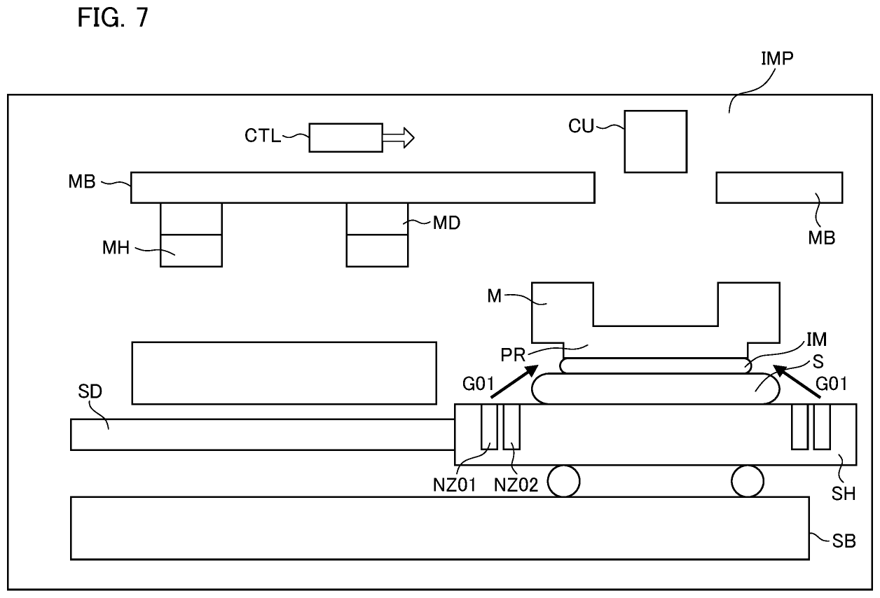

FIG. 7 is a diagram showing the state of the film forming apparatus during exposure according to the second embodiment. By stopping the supply of the second gas when the supply of the first gas starts, the first gas G01 that has been supplied from the gas nozzle NZ01 can be reliably supplied to the protruding portion of the curable composition IM, which is interposed between the mold M and the substrate S, as shown by the arrow in FIG. 7.

As a result, the oxygen concentration in the protruding portion can be reliably increased, and curing of the protruding portion due to exposure can be more reliably prevented. Note that, although, in FIG. 7, the gas nozzle NZ01 is schematically depicted as facing upward, the first gas G01 may be blown onto the protruding portion by disposing the nozzle in an inclined manner in the direction of the protruding portion.

Additionally, in the examples as shown in FIGS. 5 and 7, the gas nozzle NZ01 is disposed on the side of the substrate holding unit SH. However, if the gas nozzle NZ01 and the piping leading to the gas nozzle are additionally provided on the side of the substrate holding unit SH, which is the driving unit, the apparatus configuration becomes complicated.

Hence, the gas nozzle NZ01 may be disposed on the side facing the substrate holding unit SH. That is, the first gas supply unit (gas nozzle NZ01) and the second gas supply unit (gas nozzle NZ02) may be provided on the opposite sides to each other on the substrate holding unit.

In that case, the gas nozzle NZ01 may be held on the mold surface plate MB that holds the mold drive unit MD. As a result, the first gas G01 that is supplied from the gas nozzle NZ01 can be reliably supplied to the protruding portion of the curable composition IM, without complicating the apparatus configuration.

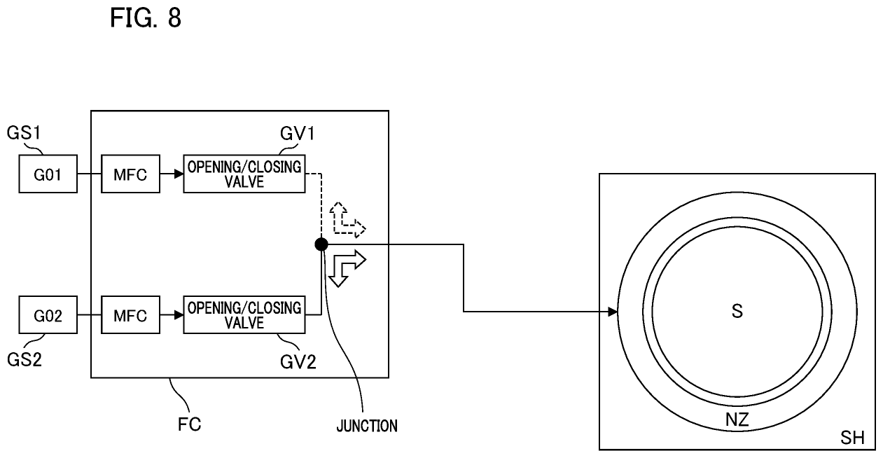

In the above example, although the configuration is such that the gas nozzles NZ01, 02 respectively supplying the first gas G01 and the second gas G02 are individually provided, the gas nozzles NZ01, 02 are not necessarily provided individually, and the same gas nozzles NZ may be shared as shown in FIG. 8.

FIG. 8 is a diagram showing a modification of the gas supply unit of the second embodiment. In FIG. 8, the pipes of the first gas G01 and the second gas G02 are joined together at a portion of the pipe leading to the same shared gas nozzle NZ (hereinafter, referred to as a “junction”). That is, the first gas supply unit (gas nozzle NZ01) and the second gas supply unit (gas nozzle NZ02) are shared.

In addition, in the case in which the first gas G01 is supplied to the shared gas nozzle NZ, an opening/closing valve GV1 is opened and an opening/closing valve GV2 may be closed so that the flow rate adjusting device MFC of the first gas G01 is connected to the gas nozzle NZ, as shown by the broken line in FIG. 8.

In contrast, when the second gas G02 is supplied to the shared gas nozzle NZ, the opening/closing valve GV2 may be opened and the opening/closing valve GV1 is closed in such a manner that the flow rate adjusting device MFC of the second gas G02 is connected to the gas nozzle NZ, as shown by the solid line in FIG. 8.

Alternatively, a three way valve may be provided in the junction to switch the flow rate adjusting units that are connected to the gas nozzles NZ. Alternatively, the flow rate of one of the flow rate adjusting unit MFC for the first gas G01 and the flow rate adjusting unit MFC for the second gas G02 may be set to zero, and the flow rate of the other flow rate adjusting unit MFC may be set to a predetermined amount or more. As a result, one of the first gas G01 and the second gas G02 can be supplied to the area around the substrate S, without providing a plurality of gas nozzles NZ.

### Third Embodiment

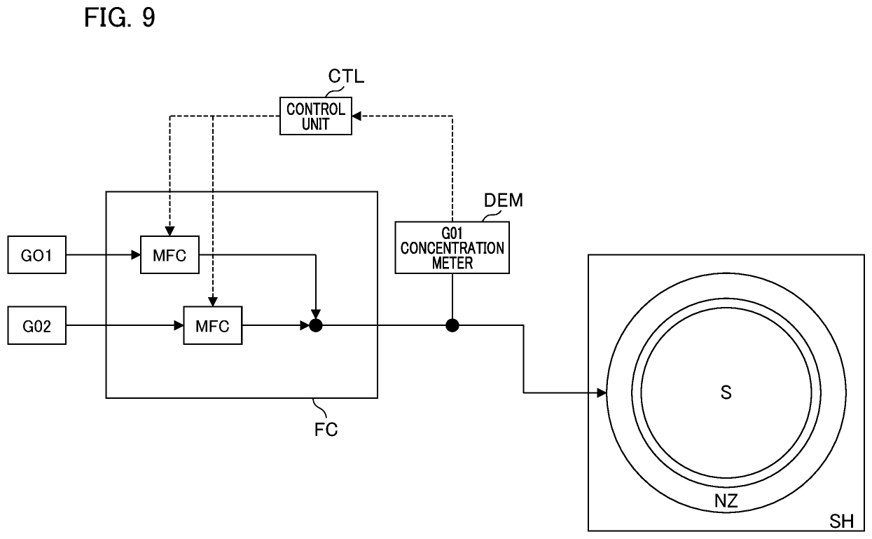

FIG. 9 is a diagram showing a configuration example of a gas supply unit according to the third embodiment. In the second embodiment, one of the first gas and the second gas can be supplied from the gas nozzle NZ.

The third embodiment is different from the second embodiment on the point that the first gas and the second gas are mixed and a gas having an arbitrary first gas concentration can be supplied from the gas nozzle NZ. In the third embodiment, it is possible to supply a gas having a desired concentration, which is lower in oxygen concentration than the first gas and higher in oxygen concentration than the second gas, from the gas nozzle NZ.

In general, the oxygen concentration at which curing of the protruded resin can be prevented varies depending on the type of the curable composition IM. Typically, the curable composition IM is prepared so as to have a plurality of characteristics including the ease of curing, such as fillability and etching resistance. However, these characteristics are often trade-offs and difficult to keep in balance. Accordingly, the curable composition IM, which is more resistant to curing, may be adopted because another characteristic is prioritized.

Assuming a curable composition that is more curable, it is assumed that a first gas having an oxygen concentration at which the protruding portion does not cure is selected, and then the change to a curable composition that is more resistant to curing is performed. In this case, the oxygen concentration of the first gas initially selected may be too high for the curable composition that is more resistant to curing after the change.

Specifically, in the case of exposure under this oxygen concentration environment, there is a concern that curing becomes too difficult, which prevents the curing of the curable composition that is interposed between the mold M and the substrate S, in addition to the curable composition that protrudes.

In the case of a configuration in which the oxygen concentration of the gas that is supplied from the gas nozzle NZ can be changed only between a binary of high and zero, as in the second embodiment, the first gas needs to be selected again to handle such a situation, which is not easy.

By making it possible to supply a gas having a desired concentration, which is lower in oxygen concentration than the first gas and higher in oxygen concentration than the second gas, as in the third embodiment, a gas having an optimal oxygen concentration can be supplied to the curable composition. As a result, even when the type of curable composition is changed, only the curable composition that protrudes being cured can be prevented.

To realize this, in the third embodiment, the pipes that are respectively connected to the flow rate adjustment devices MFC for the first gas and the second gas are joined together on the way toward the gas nozzle NZ and connected to the gas nozzle NZ that is disposed so as to surround the substrate S, as shown in FIG. 9. Consequently, a mixing unit that mixes the first gas and the second gas and supplies a mixed gas to the curable composition is configured, and, in the pipe that follows the joining, the first gas and the second gas are mixed.

The control unit CTL changes the mixing ratio (flow rate ratio) of the first gas and the second gas in the flow rate adjustment device MFC, so that a mixed gas having an arbitrary oxygen concentration, which is lower in oxygen concentration than the first gas and higher in oxygen concentration than the second gas, can be supplied to the gas nozzle NZ.

As shown in FIG. 9, an oxygen concentration meter DEM may be provided in part of the pipe that follows the joining. This oxygen concentration meter directly measures the oxygen concentration of the mixed gas. The control unit controls the mixture ratio (flow rate ratio) of the first gas and the second gas so as to obtain a predetermined value that is appropriate to the characteristics of the curable composition, based on the oxygen concentration that has been measured by the oxygen concentration meter.

Alternatively, whether or not the oxygen concentration has reached the level estimated from the flow rate ratio may be monitored, and a warning may be issued to the user if the oxygen concentration is different from the estimated one.

After the pipes that are connected to the flow rate adjusting devices MFC for the first gas and second gas have joined, a tank section having a larger cross-sectional area and larger volume than the pipes may be provided. Alternatively, a buffer section, which has increased volume by bending the pipe several times, may be provided.

The mixture of the first gas and the second gas can be facilitated by the tank section or the buffer section, and the uniformity of the mixture can be achieved. If the oxygen concentration meter is disposed at the position following the passage of the tank section, the buffer section, and the like, measurement error due to uneven oxygen concentration in the gas mixture can be reduced.

Note that, to obtain an appropriate flow rate ratio and oxygen concentration, it is desirable to perform experiments several times in advance. It is desirable that the film forming operation is performed by changing the flow rate ratio or the oxygen concentration under some condition, and that it is confirmed that the curable composition that protrudes is not cured or the curable composition that does not protrude is cured.

Whether or not the curable composition is cured can be determined by observation by using an optical microscope and the like. Although the cured resin remains as it is even after a lapse of time, the uncured resin does not remain after a lapse of sufficient time because the uncured resin is volatilized. Therefore, the presence or absence of curing or non-curing can be determined by observing the area around the pattern region by using an optical microscope.

Note that, if the flow rate of the second gas that blows out of the nozzle is lowered in an attempt to relatively increase the oxygen concentration in the vicinity of the curable composition, which is mixed with the surrounding air, the flow rate of the gas that blows onto the curable composition that protrudes also decreases. If the flow rate of the blown gas decreases, the curable composition is less volatile, and if the uncured curable composition remains unvolatilized, it may cause some failure.

Thus, if the flow rate of the second gas is lowered in an attempt to relatively increase the oxygen concentration, there are the advantage of being harder to cure and the disadvantage of being harder to volatilize due to reduced flow rate, so adjustment is very difficult.

However, in the third embodiment, the concentration of oxygen that is blown out of the gas nozzle can be changed by changing the flow rate ratio between the first gas and the second gas, without changing the total flow rate of the gas that is blown out of the gas nozzle.

Consequently, it is possible to change only the oxygen concentration of the gas without changing the flow rate of the gas that is blown onto the curable composition that protrudes, and adjustment such that the curable composition that is interposed between the mold M and the substrate S is cured while preventing only the curable composition that protrudes from being cured is possible.

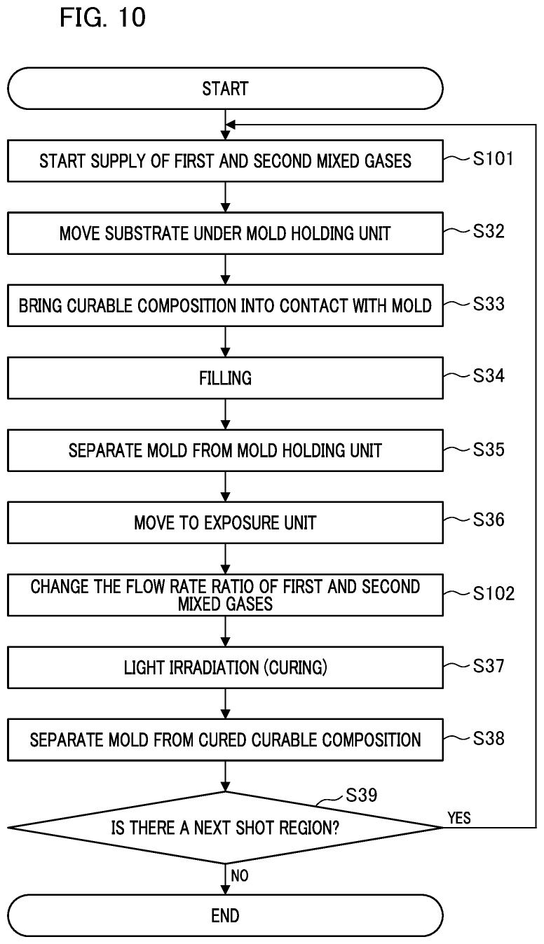

FIG. 10 is a flow chart showing an example of the processing procedure of the film forming apparatus of the third embodiment, and a preferred method of performing the third embodied will be described with reference to the flowchart in FIG. 10.

Note that the operation of each step of the flowchart in FIG. 10 is performed by the CPU, which serves as a computer in the control CTL, executing a computer program that is stored in the memory. Note that steps S32 to S39 in FIG. 10 are the same processes as the steps with the same reference numerals in FIG. 3, and description thereof will be omitted.

FIG. 10 is different from the first and second embodiments on the point that the mold M is separated from the mold holding unit MH and the flow rate ratio between the first gas and the second gas is changed in step S102, which is after the move to the exposure unit CU is started in step S36.

That is, in step S101, which is before the change of the flow rate ratio, the flow rate of the first gas is set to be greater than the flow rate of the second gas, and the supply of a mixture of the first gas and the second gas starts.

Additionally, in step S102, the flow rate ratio of the mixed gas of the first gas and the second gas is changed. At that time, the flow rate ratio is changed so that the flow rate of the first gas is lower than the flow rate of the second gas. That is, the ratio of the flow rate of the second gas to the flow rate of the first gas is set to be higher in the state of exposure by the exposure unit than in the state in which the mold is brought into contact with the curable composition by the film forming operation unit.

As a result, the curing of the protruded resin can be prevented without inhibiting the filling of the curable composition due to the first gas, and the sufficient flow rate of the mixed gas can be supplied, so that volatilization of the protruding resin can be promoted.

Note that, in the example of FIG. 10, the flow rate ratio between the first gas and the second gas is changed in the step S102. That is, the mixing ratio is set to be different between the state in which the curable composition is exposed by the exposure unit and the state in which the mold is brought into contact with the curable composition by the film forming operation unit.

However, it is sufficient that the timing of changing the flow rate ratio between the first gas and the second gas is after the completion of filling of the mold M with the curable composition 1M in step S34 and before the exposure in step S37. As a result, it is possible to reduce the possibility that the first gas inhibits the filling.

Note that the oxygen concentration at which the curing of the curable composition that protrudes can be prevented also varies depending on an exposure amount represented by the product of the illuminance of the exposure light applied to the curable composition that protrudes and the exposure time. Here, the exposure amount is not limited to the amount described above, and may be a value represented by the product of the square root of the illuminance of the exposure light and the exposure time.

For example, the illuminance of exposure light can decrease due to the deterioration of the light source. However, exposure time cannot be easily extended because productivity is reduced. Accordingly, the curable composition that can cure the pattern region within a permitted exposure time, even when the illuminance of the exposure light decreases, is selected.

Hence, before the light source deteriorates, the curable composition is easier to be cured, and the curable composition at the protruding portion is also easier to be cured. If the oxygen concentration of the first gas is determined based on the illuminance before the light source deteriorates, there is a concern that the curing of the resin that is interposed between the mold M and the substrate S, in addition to the resin that protrudes, may be prevented when the light source deteriorates and the illuminance decreases.

In the case of a configuration in which the oxygen concentration of the gas that is supplied from the gas nozzle NZ can be controlled only between the binary of high and low, as in the second embodiment, it is difficult to handle such a situation. In contrast, when the oxygen concentration blown out from the gas nozzle can be adjusted as in the third embodiment, it becomes possible to reliably cure the curable composition that is interposed between the mold M and the substrate S without curing of the curable composition that protrudes even if the illuminance of the light source deteriorates.

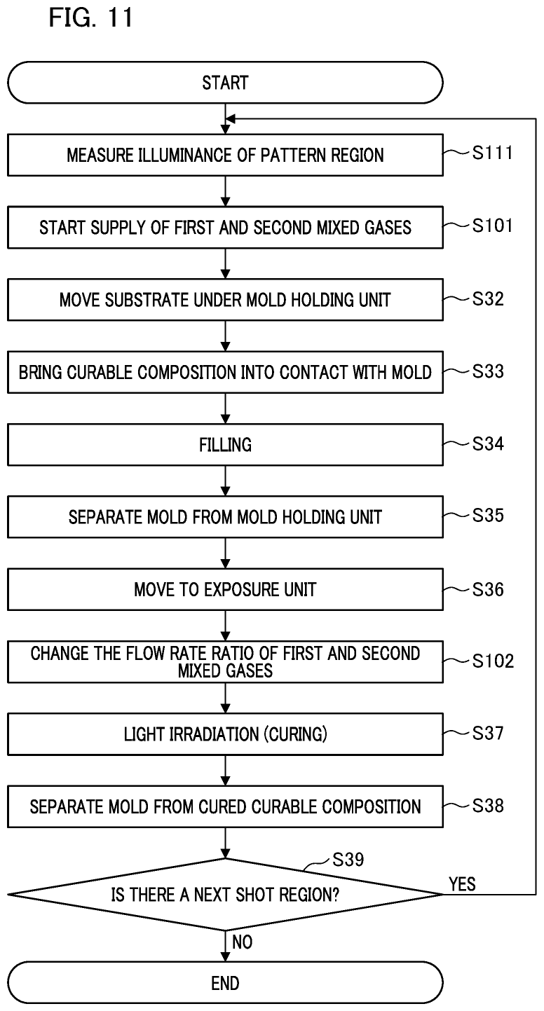

FIG. 11 is a flow chart showing the processing procedure of a modification of the film forming apparatus of the third embodiment and a preferred procedure for carrying out an adjusting method of the flow rate ratio between the first gas and the second gas based on the illuminance of exposure light will be described with reference to the flowchart in FIG. 11.

Note that the operation of each step of the flowchart in FIG. 11 is performed by the CPU, which serves as a computer in the control CTL, executing a computer program that is stored in the memory. Additionally, steps S32 to S39, steps S101, and S102 in FIG. 11 are the same processes as the steps with the same reference numerals in FIG. 10, and description thereof will be omitted.

In FIG. 11, in step S111, the illuminance of the pattern region is measured first in the exposure unit, which is different from the above embodiments, and ratio between the first gas and the second gas is changed according to the illuminance of the pattern region measured in step S111, so that the oxygen concentration after the change of the flow rate or mixing ratio (flow rate) corresponding to the oxygen concentration is determined.

Consequently, the gas can be supplied by changing the flow rate ratio between the first gas and the second gas so as to have an optimum oxygen concentration according to the illuminance, even when the illuminance of the light source deteriorates. As a result, it becomes possible to cure the curable resin that is interposed between the mold M and the substrate S while preventing only the curable resin that protrudes from being cured.

An example of a specific illuminance measurement method in FIG. 11 will be described with reference to FIG. 1. As shown in FIG. 1, the substrate holding unit SH that holds the substrate S has the illuminance measuring unit DM at its end. The illuminance measuring unit DM includes a sensor capable of measuring illuminance at a predetermined point. In step S111, the substrate holding unit SH is moved so that the illuminance measuring unit DM reaches a position corresponding to a predetermined point within the pattern region PR of the mold M.

In addition, at this position, the exposure light is emitted from the exposure unit CU, and the illuminance is measured by the illuminance measuring unit DM, so that the illuminance at a given point within the pattern region PR can be measured. The illuminance measurement is repeated while moving the substrate holding unit SH in such a manner that the position of the illuminance measuring unit DM is gradually changed within the range of the pattern region PR, and thereby, the illuminance distribution in the measurement range of the pattern region can be obtained.

Note that, for example, the illuminance of the area around the end portion of the curable composition may be measured instead of measuring the illuminance of the entire pattern region. Additionally, an amount of exposure may be measured, instead of the illuminance.

To obtain the appropriate oxygen concentration and flow rate ratio for a given exposure, it is desirable that experiments are performed several times. It is desirable that the film formation is performed by changing the exposure amount represented by the product of the illuminance and the time, the oxygen concentration, or the flow rate ratio under several conditions, and that it is actually confirmed that the curable composition that protrudes is not cured and the curable composition that does not protrude is cured. Whether or not the curable composition is cured may be determined by observation with an optical microscope and the like.

It is possible to obtain an appropriate oxygen concentration for the illuminance when the exposure time is fixed based on a series of experimental results regarding the presence or absence of curing of the curable composition in the protruding portion and pattern region under the exposure amount and oxygen concentration, or flow rate ratio, obtained as described above. Alternatively, a table or function formula of a flow rate ratio can be obtained. At that time, the table or the function formula may also include the change of exposure time.

This table or functional formula is stored in a memory, the table or functional formula is referred to based on the illuminance measured in step S111, and the appropriate oxygen concentration or flow rate ratio in step S102 can be determined.

For example, if the illuminance or the exposure amount measured in the step S111 decreases, a determination of decreasing the oxygen concentration or the flow rate ratio of the first gas in step S102 based on the above table is performed.

### Fourth Embodiment (Example of a Manufacturing Method of Film Forming Article)

Next, a manufacturing method of an article (for example, a semiconductor IC element, a liquid crystal display element, and MEMS) using the film forming apparatus as described above will be explained. In the method for manufacturing an article, a film forming step of forming a film on a substrate (for example, a wafer and a glass substrate) coated with a photosensitive agent is executed by using the film forming apparatus as described above.

Further, a step of developing a substrate (photosensitive agent) on which a film is formed and other well-known manufacturing steps on the developed substrate are executed. Other well-known manufacturing steps include etching, resist removing, dicing, bonding, packaging, and the like. According to such an article manufacturing method, it is possible to manufacture an article with higher quality than the conventional ones.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions.

In addition, as a part or the whole of the control according to the embodiments, a computer program realizing the function of the embodiments described above may be supplied to the film forming apparatus through a network or various storage media. Then, a computer (or a CPU, an MPU, or the like) of the film forming apparatus may be configured to read and execute the program. In such a case, the program and the storage medium storing the program configure the present invention.

This application claims the benefit of Japanese Patent Application No. 2022-132227, filed on Aug. 23, 2022, which is hereby incorporated by reference herein in its entirety.

What is claimed is:

1. A film forming apparatus comprising:
a film forming operation unit configured to bring a mold into contact with a curable composition supplied to a substrate;
an exposure unit configured to expose the curable composition;
a moving unit configured to move the substrate from the film forming operation unit to the exposure unit; and
a control unit, including at least one processor or circuit, configured to perform control such that a concentration of a first gas that inhibits curing of the curable composition becomes higher in a state in which the curable composition is exposed by the exposure unit after the substrate is moved by the moving unit than in a state in which the mold is brought into contact with the curable composition by the film forming operation unit.

2. The film forming apparatus according to claim 1, further comprising:
a second gas supply unit configured to supply a second gas that does not inhibit curing of the curable composition to the curable composition before the mold is brought into contact with the curable composition by the film forming operation unit.

3. The film forming apparatus according to claim 2, wherein the control unit performs control such that a concentration of the second gas becomes lower in a state in which the curable composition is exposed by the exposure unit than in a state in which the mold is brought in contact with the curable composition by the film forming operation unit.

4. The film forming apparatus according to claim 3, wherein the second gas supply unit reduces a supply amount of the second gas supplied to the curable composition in a state where the curable composition is exposed by the exposure unit, more than the supply amount of the second gas supplied to the curable composition before the mold is brought into contact with the curable composition by the film forming operation unit.

5. The film forming apparatus according to claim 4, wherein the second gas supply unit stops the supply of the second gas to the curable composition in a state in which the curable composition is exposed by the exposure unit.

6. The film forming apparatus according to claim 1, further comprising a first gas supply unit configured to supply the first gas to the curable composition before the curable composition is exposed by the exposure unit.

7. The film forming apparatus according to claim 6, wherein the first gas supply unit starts supplying the first gas to the curable composition after the operation of bringing the mold into contact with the curable composition by the film forming operation unit is completed.

8. The film forming apparatus according to claim 1, further comprising:
a mixing unit configured to mix a second gas that does not inhibit curing of the curable composition and the first gas, and supply the mixed gas to the curable composition.

9. The film forming apparatus according to claim 1, wherein the control unit controls a mixing ratio of the first gas and a second gas that does not inhibit curing of the curable composition.

10. The film forming apparatus according to claim 9, wherein the control unit causes the mixing ratio to be different between a state in which the curable composition is exposed by the exposure unit and a state in which the mold is brought into contact with the curable composition by the film forming operation unit.

11. The film forming apparatus according to claim 9, further comprising an oxygen concentration meter,
wherein the control unit controls the mixing ratio based on an oxygen concentration measured by the oxygen concentration meter.

12. The film forming apparatus according to claim 9, wherein the control unit changes the mixing ratio according to an illuminance or an exposure amount in the exposure unit.

13. The film forming apparatus according to claim 2, wherein the second gas is a gas for promoting filling or diffusion of the curable composition.

14. The film forming apparatus according to claim 2, wherein a supply unit of the first gas and a supply unit of the second gas are provided in a substrate holding unit for holding the substrate.

15. The film forming apparatus according to claim 2, wherein a supply unit of the first gas and a supply unit of the second gas are provided on the opposite sides to each other.

16. The film forming apparatus according to claim 14, wherein the supply unit of the first gas and the supply unit of the second gas are shared.

17. The film forming apparatus according to claim 9, wherein the control unit performs control such that a ratio of a flow rate of the second gas to a flow rate of the first gas is higher in a state in which the curable composition is exposed by the exposure unit than in a state in which the mold is in brought into contact with the curable composition by the film forming operation unit.

18. The film forming apparatus according to claim 1, wherein the first gas contains at least oxygen.

19. The film forming apparatus according to claim 1, wherein the film forming operation unit has a mold holding unit for holding the mold, and the exposure unit is disposed at a position where exposure light is not blocked by the mold holding unit.

20. A film forming method comprising:
performing a film forming operation in which a mold is brought into contact with a curable composition supplied to a substrate;
exposing the curable composition;
moving the substrate for the exposing after performing the performing a film forming operation; and
performing control such that a concentration of a first gas that inhibits curing of the curable composition becomes higher in the exposing after the substrate is moved in the moving than in the performing film forming operation.

21. A manufacturing method of an article comprising:
performing a film forming operation in which a mold is brought into contact with a curable composition supplied to a substrate;
exposing the curable composition;
moving the substrate for the exposing after performing the performing a film forming operation;
performing control such that a concentration of a first gas that inhibits curing of the curable composition becomes higher in the exposing after the substrate is moved in the moving than in the performing film forming operation; and
manufacturing an article from the substrate fill the film has been formed.

22. A non-transitory computer-readable storage medium storing a computer program including instructions for executing following processes:
performing a film forming operation in which a mold is brought into contact with a curable composition supplied to a substrate;
exposing the curable composition;
moving the substrate for the exposing after performing the performing a film forming operation; and
performing control such that a concentration of a first gas that inhibits curing of the curable composition becomes higher in the exposing after the substrate is moved in the moving than in the performing film forming operation.
